(19) United States
(12) Patent Application Publication
(10) Pub. No.: US 2005/0153481 A1
(43) Pub. Date: Jul. 14, 2005

(54) Method of pretreating a nonmagnetic substrate and a magnetic recording medium formed thereby

(76) Inventors: Youichi Tei, Nagano (JP); Kengo Kainuma, Nagano (JP); Teruhisa Yokosawa, Nagano (JP)

Correspondence Address: Marc A. Rossi;ROSSI & ASSOCIATES, P.O. Box 826, Ashburn, VA, 20146-0826, US

(21) Appl. No.: 11/015,345

(22) Filed: Dec. 17, 2004

(30) Foreign Application Priority Data
Dec. 18, 2003 (JP) JPPA 2003-421604

(51) Int. Cl. H01L 21/44; H01L 21/48; H01L 21/50

(52) U.S. Cl. 438/123

(57) ABSTRACT

A glass substrate is pretreated before forming a Ni—P plating layer thereon. The pretreating process includes degreasing and glass activation treatments of the surface of the nonmagnetic substrate, applying a nickel chelate agent or a nickel soap agent on the substrate surface, a metallizing baking treatment of the nickel-containing agent, an activation treatment of the metallized nickel film to form a nickel adhesion layer, a treatment to form a palladium catalyst layer on the nickel adhesion layer, forming the Ni—P plating layer on the palladium catalyst layer by electroless plating in the range of phosphorus concentration of 1 to 13 wt %, and heat treating the Ni—P plating layer.

This application is based on, and claims priority to, Japanese Application No. 2003-421604, filed on Dec. 18, 2003, the entire content of which is incorporated herein by reference.

### BACKGROUND

Conventional nonmagnetic substrates are typically made of aluminum alloys. The current trend is to make hard disk devices having a larger capacity and yet smaller size and lighter in weight. Accordingly, a magnetic disk needs to be flatter, have a smaller diameter, and thinner than conventional ones. Since a conventional substrate of an aluminum alloy is difficult to cope with the demand of the market, glass is increasingly favored as a substrate material. It is, however, technologically difficult to form a Ni—P layer on a glass substrate by an electroless plating method with enough adhesivity, homogeneity, and smoothness. To form a Ni—P layer having such desired properties to obtain a well performing magnetic disk, various methods of pre- and post- treatments have been proposed for the electroless plating process.

For example, Japanese Unexamined Patent Application Publication No. H1-176079 discloses electroless plating after treating the substrate in an aqueous solution containing palladium chloride and stannous chloride, followed by a treatment in a solution of alkali carbonate, a solution of alkali hydrogencarbonate, or a solution of a mixture of the two compounds. Japanese Unexamined Patent Application Publication No. S53-19932, for example, discloses electroless plating after a series of pretreatments including two-stage etching with a chromic acid-sulfuric acid mixed solution and with a nitric acid solution, etching with a strong alkaline solution, sensitizing treatment with dilute stannous chloride, and activation treatment with a silver salt solution and a palladium salt solution. Japanese Unexamined Patent Application Publication No. S48-85614, for example, discloses electroless plating after pretreatments including cleaning with warm liquid of sulfuric acid and potassium bichromate, sensitization with stannous chloride made acidic by hydrochloric acid, and activation with a palladium chloride solution. Also proposed is a method in which electroless plating is done after pretreatments of alkaline degreasing, etching with hydrofluoric acid, sensitizing with stannous chloride solution, and activation with palladium chloride solution.

Further, Japanese Unexamined Patent Application Publication No. H7-334841, for example, discloses plating after the following treatments: adequate degreasing of the glass substrate, etching to enhance anchoring effect, removing contaminants adhered on the substrate surface during the etching process, chemically homogenizing the substrate surface by surface modulation process, sensitizing treatment, and activation treatment. Preferable materials disclosed are an aqueous solution containing hydrofluoric acid and potassium hydrofluoride for etching, hydrochloric acid for removing surface contaminants, and an aqueous solution containing sodium methoxide for surface modulation.

Japanese Unexamined Patent Application Publication No. 2000-163743, for example, discloses pretreating on the surface of a glass substrate as follows: sequentially degreasing, etching, warm pure water treatment, silane coupling agent treatment, activation treatment, and acceleration treatment, and then carry out electroless plating, followed by heat treatment. Preferable materials disclosed are amino silane coupling agent for the silane coupling agent, aqueous solution of palladium chloride for activator, and aqueous solution of sodium hypophosphite for accelerator.

A Ni—P layer formed on a glass substrate according to any one of the above-described known methods, however, does not provide satisfactory thickness (of one to several microns), adhesiveness, homogeneity, and smoothness at that thickness, which are all required to obtain a magnetic disk having a well performing magnetic recording layer.

Therefore, there still remains a need for a method of pretreating a nonmagnetic substrate that allows formation of a Ni—P plating layer that exhibits a satisfactory thickness, adhesiveness, homogeneity, and smoothness so that a satisfactory magnetic recording layer can be formed. The present invention addresses this need.

### SUMMARY OF THE INVENTION

The present invention relates to a method of pretreating a nonmagnetic substrate so that a layer, such as a Ni—P layer, can be formed by electroless plating, for a magnetic disk, and a magnetic recording medium formed thereby.

One aspect of the present invention is a method of pretreating a nonmagnetic substrate before forming a magnetic recording layer thereon. The method includes cleaning the surface of the substrate, forming a nickel layer on the surface of the nonmagnetic substrate after cleaning, forming a palladium layer on the nickel layer, and forming a Ni—P plating layer on the palladium layer.

The substrate can be a glass substrate, cleaning the substrate surface can include degreasing the substrate surface and activating the substrate surface, and forming the Ni layer can include applying a nickel chelate agent or a nickel soap agent, metallizing baking the nickel chelate agent or the nickel soap agent, and activating the metallized nickel layer. Forming the palladium layer can include converting the palladium layer to a catalyst layer. Plating the Ni—P plating layer can include electroless plating the Ni—P plating layer, followed by heating treating the Ni—P plating layer.

The nickel layer also can be formed by baking a nickel chelate agent or a nickel soap agent to form a nickel metallic film. The palladium layer also can be formed by bonding palladium with the surface of the nickel metallic film. The Ni—P plating layer can be then formed by electroless plating after the bonding step, followed by heat treating the same.

Surface roughness of the substrate surface after the pretreatment can be at most 0.5 nm and micro surface waviness at most 0.5 nm.

The nickel chelate agent, which is the material for the nickel layer, can have a structure represented by Ni(CᵢH₂ᵢ₊₁COCⱼH₂ⱼCOCₖH₂ₖ₊₁), where i, j, and k are positive integers. The nickel soap agent, which is another material for the nickel layer, can have a structure represented by one of Ni(—OOCCH(CₙH₂ₙ₊₁)CₚH₂ₚ₊₁)₂ and Ni(—OOCCₘH₂ₘ₊₁)₂, where m, n, and o each are a positive integer of one or greater.

The step of metallizing baking can be carried out in an inert gas atmosphere and at a temperature in the range of 250° C. to 400° C. The step of converting the palladium layer to a catalyst layer can be a treatment of palladium chloride. The Ni—P plating layer can contains phosphorus in a range of 1.0 wt % to 13.0 wt % and can have a thickness of at least 1.0 μm. The heat treatment after the electroless Ni—P plating can be carried out at a temperature in a range of 250° C. to 300° C. for at least 1 hr.

Another aspect of the present invention is a magnetic recording medium comprising the nonmagnetic substrate, a magnetic recording layer formed above the substrate, and the pretreatment layer (i.e., the nickel adhesion layer formed on the substrate, the palladium catalyst layer formed on the adhesion layer, and the Ni—P plating layer formed on the catalyst layer) formed between the substrate and the magnetic recording layer by the method described above.

### BRIEF DESCRIPTION OF DRAWINGS

FIG. 1 is a flow chart outlining the process of pretreating a nonmagnetic substrate, namely made of glass.

FIG. 2 is a schematic sectional view of a magnetic recording medium manufactured employing the pretreatment method of FIG. 1.

FIG. 3 is a flow chart illustrating the pretreatment process of FIG. 1 in detail.

### DETAILED DESCRIPTION

The present invention is applicable to forming a magnetic recording medium, such as hard disk devices and external storage devices.

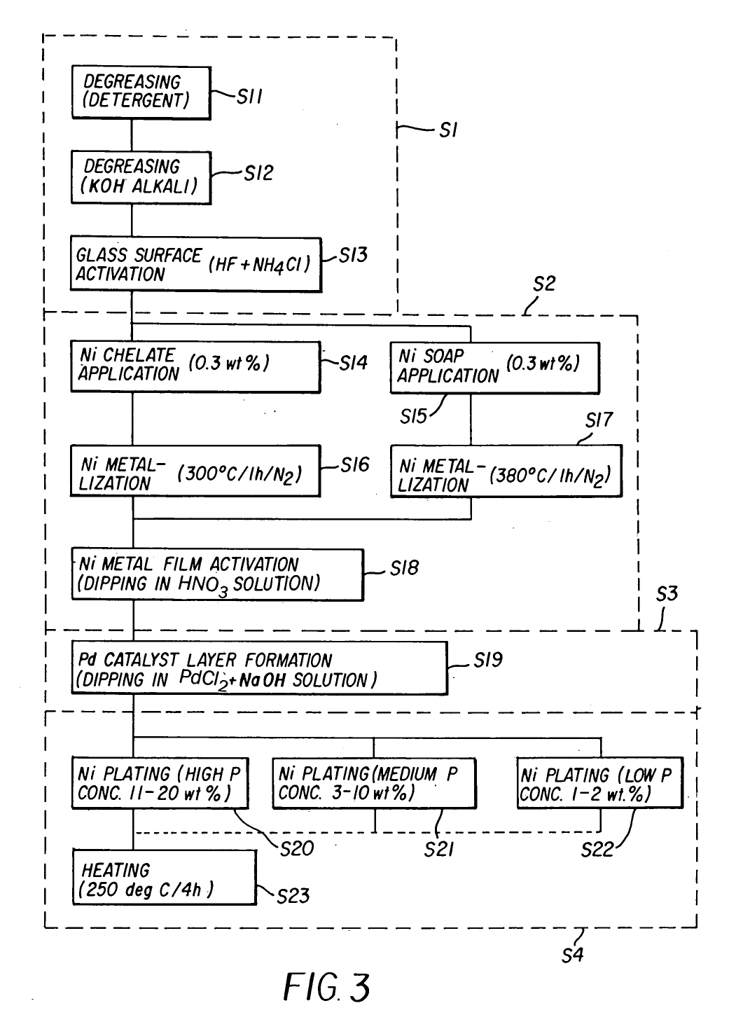

Steps S1-S4 in FIG. 1 illustrate a process of pretreating a glass (nonmagnetic) substrate. Steps S11-S23 in FIG. 3 illustrate the pretreating process of FIG. 1 in detail.

Step S1 is a step of cleaning a surface of the glass substrate 1. In the step S1, the surface of the glass substrate 1 is degreased (steps S11 and S12) and activated (step S13). Step S2 is a step of forming a nickel adhesion layer 2 on the surface of the glass substrate 1 after cleaning. In the step S2, a nickel chelate agent or a nickel soap agent is applied on the glass substrate 1 (step S14 or step S15), and a metallization baking step is carried out to the applied nickel-containing agent to obtain a metallic nickel film (step S16 or step S17). Thereafter, the metallic nickel film is activated (step S18), obtaining a nickel adhesion layer 2.

Step S3 is a step of forming a palladium catalyst layer 3 on the nickel adhesion layer 2. In the step S3, a palladium catalyst layer 3 is formed by converting palladium to a catalyst (step S19) on the nickel adhesion layer 2. Step S4 is a step of forming a Ni—P plating layer 4 on the palladium catalyst layer 3. In the step S4, a Ni—P plating layer 4 is formed by electroless Ni—P plating (steps S20 through S22), followed by a heating treatment (step S23).

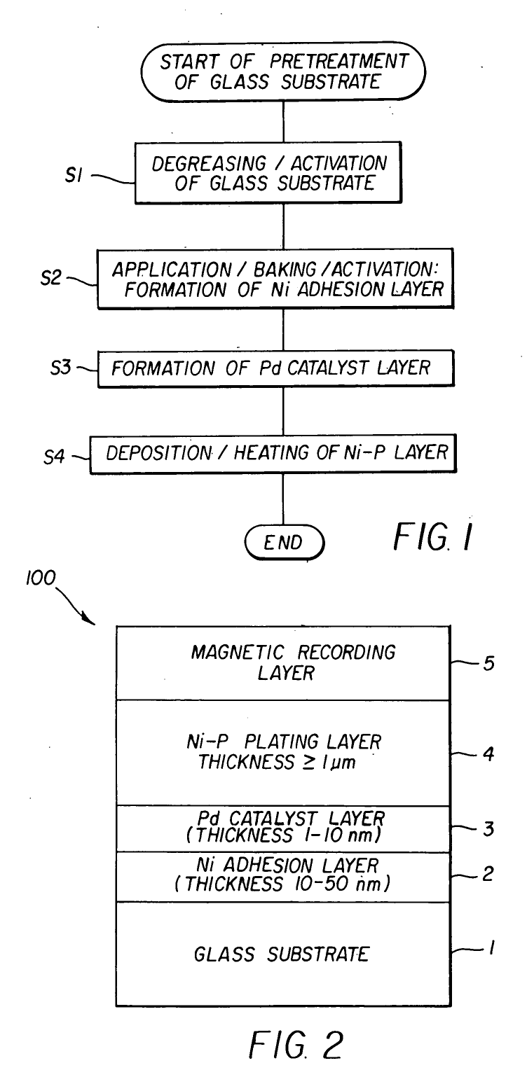

FIG. 2 illustrates a sectional structure of a magnetic recording medium 100 manufactured by the pretreatment process shown in FIGS. 1 and 3. The magnetic recording medium 100 comprises a glass substrate (nonmagnetic) 1 having a disk shape, and layers sequentially laminated on the substrate, including a nickel adhesion layer 2 having a thickness of 10 nm to 50 nm, a palladium catalyst layer 3 having a thickness of 1 nm to 10 nm, and a Ni—P plating layer 4 having a thickness of at least 1 μm. On the pretreatment layer, i.e., the layers 2 through 4, a desired magnetic recording layer 5 is formed.

The magnetic recording layer 5 is formed through the following procedure. After a Ni—P plating layer is formed on the surface of the glass substrate by an electroless plating method, the surface of the Ni—P plating 4 is subjected to a smoothing treatment and a texturing treatment. A magnetic recording layer 5 is formed by sequentially forming a nonmagnetic metallic underlayer, a magnetic layer of a thin film of a ferromagnetic alloy, a protective layer, and a liquid lubricant layer on the pretreated surface.

A magnetic recording medium 100 manufactured by the above method can be used as a magnetic disk mounted on a hard disk drive, which is an external storage device of an information processing apparatus, e.g., a computer. A Ni—P plating layer can exhibit sufficient thickness of one to several microns, and can provide satisfactory adhesiveness, homogeneity, and smoothness at that thickness.

The following describes in detail each step in the pretreatment process shown in FIG. 3. The surface of the glass substrate 1 is cleaned (steps S11 and S12) by degreasing the surface and removing organic coating layers and particles. After cleaning, an activation treatment (step S13) is conducted on the surface of the glass substrate 1 by dipping the same in a dilute acid solution to peel off inactive oxide films existing on the surface of the glass substrate 1 and to modify the functional groups on the surface of the glass substrate 1 into reactive silanol groups (Si—OH).

On the surface of the glass substrate 1 covered with reactive silanol groups (Si—OH), an appropriate amount of a nicked chelate agent (represented by structure (1) below) or a nickel soap agent (represented by structure (2) below) is applied (steps S14 or S15). The agent becomes an adhesion layer material between the glass substrate 1 and the Ni—P plating layer 4.

The nickel chelate agent for the adhesion layer material is represented by the following general structure (1):
Ni(CᵢH₂ᵢ₊₁COCⱼH₂ⱼCOCₖH₂ₖ₊₁) (1),
where i, j, and k are positive integers.

The nickel chelate agent is preferably, for example, nickel acetylacetonate represented by structure (3) below, nickel propioneacetonate represented by structure (4) below, nickel propioneethylate represented by structure (5) below, or a mixture of these substances:
Ni(CH₃COCH₂COCH₃) (3)
Ni(C₂H₅COCH₂COCH₃) (4)
Ni(C₂H₅COCH₂COC₂H₅) (5)

The nickel soap agent, which is another material for the adhesion layer, is represented by the following general structures (2) and (2′):
Ni(—OOCCH(CₙH₂ₙ₊₁)CₚH₂ₚ₊₁)₂ (2)
Ni(—OOCCₘH₂ₘ₊₁)₂ (2′),
wherein m, n, and p each are a positive integer of one or greater.

The nickel soap agent is preferably nickel 2-ethylhexanoate represented by the following structure (6) or nickel stearate represented by the following structure (7), for example:
Ni(—OOCCH(C₂H₅)C₄H₉)₂ (6)
Ni(—OOCC₁₇H₃₅)₂ (7)

In the subsequent process of baking at an appropriate temperature under an inert gas atmosphere, the nickel chelate agent or the nickel soap agent is thermally modified, organic compounds are decomposed and volatilized, and a metallic component nickel makes substitution reaction with the silanol group previously modulated and generated on the surface of the glass substrate 1, obtaining a nickel metallic film composed of dehydrogenated nickel silanoxide (Si—ONi) (steps S16 or S17). The nickel metallization baking treatment can be conducted at a temperature in the range of 250° C. to 350° C. for the nickel chelate agent, while at a temperature in the range of 300° C. to 400° C. for the nickel soap agent, for at least 30 min.

Subsequent activation treatment, such as by an acid treatment, for the nickel metallic film peels off the nickel oxide film that forms outermost several nanometer layer of the nickel metallic film (step S18). In Step S19, a palladium catalyst generating treatment is appropriately conducted to provide a catalyst layer for precipitation of Ni—P plating. In Steps S20-S23, electroless Ni—P plating is conducted under predetermined conditions set forth below.

A plating solution to form the Ni—P plating layer 4 can be selected from any Ni—P plating solution exhibiting nonmagnetic or soft magnetic property with a phosphorus concentration in the range of 1 to 13 wt %. Specific examples of the plating solutions include: so-called nonmagnetic high phosphorus concentration type Ni—P plating solution (phosphorus concentration from 11 to 13 wt %, for example NIMUDEN HDX, a product of C. Uyemura & Co., Ltd.), nonmagnetic or soft magnetic, medium phosphorus concentration type Ni—P plating solution (phosphorus concentration from 6 to 8 wt %, for example MELPLATE NI-867, a product of Meltex Inc., and phosphorus concentration from 3 to 6 wt %, for example MELPLATE NI-802, a product of Meltex Inc.), and soft magnetic low phosphorus concentration type Ni—P plating solution (phosphorus concentration from 1 to 2 wt %, for example NIMUDEN LPY, a product of C.Uyemura & Co., Ltd., and TOP NICORON LPH, a product of Okuno Chemical Industries Co., Ltd.).

The Ni—P plating layer can also be formed using a higher phosphorus concentration type Ni—P plating solution with phosphorus concentration higher than 14 wt % that is commercially available and facilitates precipitation of the plating. Various types of Ni—P plating is employed, depending on each purpose, including the nonmagnetic high phosphorus concentration Ni—P plating, the nonmagnetic or soft magnetic medium phosphorus concentration Ni—P plating, and the soft magnetic low phosphorus concentration Ni—P plating, as described below.

The nonmagnetic high phosphorus concentration Ni—P plating layer formed on a nonmagnetic glass substrate allows:
(1) to obtain exact smoothness for attaining high density recording that is difficult with high rigidity glass substrate;
(2) to manufacture an anisotropically aligned medium employing LZT (laser zone texturing) or tape texturing; and
(3) to enhance coercivity of a magnetic film by applying a bias voltage on the substrate in the sputtering process.

The soft magnetic low phosphorus concentration Ni—P plating film formed on a nonmagnetic glass substrate can be used for a soft magnetic backing layer of a perpendicular magnetic recording medium. A perpendicular magnetic recording medium exhibiting high recording density can be obtained by a double layer perpendicular magnetic recording medium in which soft magnetic film called a soft magnetic backing layer is provided under a magnetic recording layer that carries information recording function. The backing layer has a high saturation magnetic flux density and facilitates flow of magnetic flux generated by the magnetic head.

The nonmagnetic or soft magnetic, medium phosphorus concentration Ni—P plating layer formed on a nonmagnetic glass substrate can be used for an underlayer plating film (striking plating), which is an adhesion layer, between a low phosphorus concentration Ni—P plating film and the nonmagnetic substrate, as well as applications that use the high phosphorus concentration Ni—P plating film and the low phosphorus concentration Ni—P plating film.

Subsequent heating treatment (at 250° C. for 4 hr) completes formation of an electroless Ni—P plating layer 4 having a thickness of at least 1.0 μm that exhibits excellent adhesiveness, homogeneity, and smoothness. The heat treatment, after the electroless Ni—P plating is formed, can be achieved at a temperature in the range of 250° C. to 300° C. for at least 1 hr in an inert gas atmosphere.

The degree of surface roughness Ra of the glass substrate 1 affects physical anchoring effect on the adhesiveness of the Ni—P plating layer 4. For surface roughness Ra larger than 0.5 nm, there is certain expectation of enhancement of adhesiveness of the Ni—P plating layer 4. For surface roughness Ra smaller than 0.5 nm, physical anchoring effect is hardly expected on an ultra smooth glass substrate 1. Nevertheless, the present method can be applied to form an ultra smooth glass substrate 1 with the surface roughness smaller than 0.5 nm, while exhibiting satisfactory adhesiveness of the Ni—P plating layer 4.

As described previously, a strong chemical bond is developed between the glass substrate 1 and the nickel adhesion layer 2 at the interface on the glass substrate 1 by generation of the dehydrogenized nickel silanoxide (Si—ONi) from the silanol group (Si—OH) on the glass substrate 1 and the nickel chelate agent or the nickel soap agent, which is the material of the nickel adhesion layer 2. The chemical bond assures sufficient adhesiveness of the Ni—P plating layer 4 even on an ultra smooth glass substrate 1.

A Ni—P plating layer 4 formed on a glass substrate 1 obtained according to the present method can provide a sufficient thickness (in the range of 1 μm to 5 μm) while exhibiting satisfactory adhesiveness, homogeneity, and smoothness at that thickness range, which are necessary to obtain a magnetic disk having an excellent property of the magnetic recording layer 5, using any Ni—P plating solution exhibiting nonmagnetic or soft magnetic property.

Specific examples of the above method are described referring to Table 1 and Table 2.

Table 1 shows treatment conditions for each treatment step. Treatment items in Table 1 are treatment steps, treatment liquid, concentration, temperature, treatment time, and the other. The treatment steps (1) through (9) correspond to the steps S11-S23 in FIG. 3. Specifically, step S11 corresponds to treatment (1), step S12 to treatment (2), step S13 to treatment (3), steps S14 and S15 to treatment (4), steps S16 and S17 to treatment (5), step S18 to treatment (6), step S19 to treatment (7), steps S20-S22 to treatment (8), and step S23 to treatment (9).

TABLE 1
(FOR GLASS SUBSTRATE)

| | | TREATMENT | CONCENTRATION | TEMPERATURE | | |
|---|---|---|---|---|---|---|
| TREATMENT STEP | | LIQUID | (WT %) | (° C.) | TIME | OTHER |
| (1) | detergent degreasing | alkali detergent | 1.5 | 50 | 3 min | |
| (2) | alkali degreasing | KOH | 7.5 | 50 | 3 min | |
| (3) | glass activation | HF + NH₃F | 1.0 | 20 | 3 min | |
| (4) | application of Ni | Ni acetylacetonate/ | 0.3 | 20 | — | |
| | chelate agent or | toluene | | | | |
| | Ni soap agent | Ni 2-ethyl hexanate/ | 0.3 | 20 | — | |
| | | cyclohexane | | | | |
| (5) | Ni metallizing baking | Ni acetylacetonate | — | 300 | 1 hr | in N₂ |
| | | Ni 2-ethyl hexanate | — | 380 | 1 hr | in N₂ |
| (6) | activation of Ni | HNO₃ solution | 30 | 20 | 2 min | |
| | metallic film | | | | | |
| (7) | formation of Pd | PdCl₂ + NaOH | 3.0 | 20 | 3 min | |
| | catalyst layer | | | | | |
| (8) | Ni—P plating | NIMUDENN HDX | — | 80 | 20 min | |
| | | MELPLATE NI-867 | — | 70 | 35 min | |
| | | NIMUDEN LPY | — | 80 | 25 min | |
| (9) | heating | | — | 250 | 4 hr | in N₂ |

The following Examples 1-6 have been conducted under various treatment conditions.

In Example 1, a chemically reinforced glass substrate 1 was formed with a Ni—P plating layer 4 indicated in FIG. 2 by electroless plating using the treatment steps (1)-(9) under the following conditions:
(1) Detergent degreasing: detergent concentration 1.5 wt %, a treatment at 50° C. for 3 min;
(2) Alkali degreasing: KOH concentration 7.5 wt %, a treatment at 50° C. for 3 mm;
(3) Glass surface activation: HF+NH3F concentration 1.0 wt %, a treatment at 20° C. for 3 min;
(4) Application of nickel chelate agent, a material for nickel adhesion layer: application by dipping in nickel acetylacetonate/toluene solution with nickel acetylacetonate concentration 0.3 wt %;
(5) Baking for nickel metallized film: a baking treatment in nitrogen gas atmosphere at 300° C. for 1 hr;
(6) Activation of nickel metallized film: HNO₃ concentration 30 wt %, a treatment at 20° C. for 2 min;
(7) Formation of palladium catalyst layer: concentration of PdCl₂+NaOH 3.0 wt %, a treatment at 20° C. for 3 min;
(8) Formation of Ni—P plating layer: plating solution NIMUDEN HDX (phosphorus concentration 15-20 wt % produced by C.Uyemura & Co., Ltd.), a treatment at 80° C. for 20 min (Ni—P plating layer thickness 3.0 μm);
(9) Heating of Ni—P plating layer: a heating treatment in nitrogen gas atmosphere at 250° C. for 4 hr.

In Example 2, a Ni—P plating layer 4 was formed by an electroless plating method through the same treatment steps and under the same conditions as set forth in Example 1 except for the following step and condition:
(8) Formation of Ni—P plating layer 4: plating solution MELPLATE NI-867 (phosphorus concentration 6-8 wt % produced by Meltex Inc.), a treatment at 70° C. for 35 min (Ni—P plating layer thickness 3.0 μm).

In Example 3, a Ni—P plating layer 4 was formed by an electroless plating method through the same treatment steps and under the same conditions as set forth in Example 1 except for the following step and condition:
(8) Formation of Ni—P plating layer: plating solution NIMUDEN LPY (phosphorus concentration 1-2 wt % produced by C.Uyemura & Co., Ltd.), a treatment at 80° C. for 25 min (Ni—P plating layer thickness 3.0 μm).

In Example 4, a Ni—P plating layer 4 was formed by an electroless plating method through the same treatment steps and under the same conditions as set forth in Example 1 except for the following steps and conditions:
(4) Application of nickel soap agent, a material for nickel adhesion layer: application by dipping in nickel 2-ethyl hexanate/cyclohexane solution with nickel 2-ethyl hexanate concentration 0.3 wt %;
(5) Baking for nickel metallized film: a baking treatment in nitrogen gas atmosphere at 380° C. for 1 hr;
(8) Formation of Ni—P plating layer: plating solution MINUDENN HDX (phosphorus concentration 11-13 wt %, produced by C.Uyemura & Co., Ltd.), a treatment at 80° C. for 20 min (Ni—P plating layer thickness 3.0 μm).

In Example 5, a Ni—P plating layer 4 was formed by an electroless plating method through the same treatment steps and under the same conditions as set forth in Example 1 except for the following steps and conditions:
(4) Application of nickel soap agent, a material for nickel adhesion layer: application by dipping in nickel 2-ethyl hexanate/cyclohexane solution with nickel 2-ethyl hexanate concentration 0.3 wt %;
(5) Baking for nickel metallized film: baking treatment in nitrogen gas atmosphere at 380° C. for 1 hr;
(8) Formation of Ni—P plating layer: plating solution MELPLATE NI-867 (phosphorus concentration 6-8 wt % produced by Meltex Inc.), a treatment at 70° C. for 35 min (Ni—P plating layer thickness 3.0 μm).

In Example 6, a Ni—P plating layer 4 was formed by an electroless plating method through the same treatment steps and under the same conditions as set forth in Example 1 except for the following steps and conditions:
(4) Application of nickel soap agent, a material for nickel adhesion layer: application by dipping in nickel 2-ethyl hexanate/cyclohexane solution with nickel 2-ethyl hexanate concentration 0.3 wt %;
(5) Baking for nickel metallized film: baking treatment in nitrogen gas atmosphere at 380° C. for 1 hr;
(8) Formation of Ni—P plating layer: plating solution NIMUDEN LPY (phosphorus concentration 1-2 wt % produced by C.Uyemura & Co., Ltd.), a treatment at 80° C. for 25 min (Ni—P plating layer thickness 3.0 μm).

Comparative Examples 1-3 have been conducted under various treatment conditions.

In Comparative Example 1, a chemically reinforced glass substrate 1 was formed with a Ni—P plating layer by electroless plating using the treatment steps (1) through (7) on the substrate surface under the following conditions:
(1) Detergent degreasing: detergent concentration 1.5 wt %, a treatment at 50° C. for 3 min;
(2) Alkali degreasing: KOH concentration 7.5 wt %, a treatment at 50° C. for 3 min;
(3) Roughening of glass surface: chromic acid plus sulfuric acid concentrations 40 wt % plus 40 wt %, a treatment at 60° C. for 10 min;
(4) Catalyst treatment for catalyst provision: a treatment at 20° C. for 30 min in an aqueous solution of a mixture of 0.3 g/L of PdCl₂ plus 15 g/L of SnCl₂ 2H₂O plus 200 mL/L of 36% HCl;
(5) Acceleration treatment for catalyst provision: a treatment at 50° C. for 5 min in an aqueous solution of 100 g/L of H₂SO₄;
(6) Formation of Ni—P plating layer 4: plating solution NIMUDEN HDX (phosphorus concentration 15-20 wt %, produced by C. Uyemura & Co., Ltd.), a treatment at 80° C. for 3.0 min (Ni—P plating layer thickness 0.4 μm; film deposition thicker than 0.4 μm was not possible due to peeling during the plating process);
(7) Heating of Ni—P plating layer: a treatment in nitrogen atmosphere at 250° C. for 4 hr.

In Comparative Example 2, a Ni—P plating layer 4 was formed by an electroless plating method through the same treatment steps and under the same conditions as set forth in Comparative Example 1 except for the following step and condition:
(6) Formation of Ni—P plating layer: plating solution MELPLATE NI-867 (phosphorus concentration 6-8 wt %, produced by Meltex Inc.), a treatment at 80° C. for 9.0 min (Ni—P plating layer thickness 0.7 μm; film deposition thicker than 0.7 μm was not possible due to peeling during the plating process).

In Comparative Example 3, a Ni—P plating layer was formed by an electroless plating method through the same treatment steps and under the same conditions as set forth in Comparative Example 1 except for the following step and condition:
(6) Formation of Ni—P plating layer: plating solution NIMUDEN LPY (phosphorus concentration 1-2 wt %, produced by C. Uyemura & Co., Ltd.), a treatment at 80° C. for 3.0 min (Ni—P plating layer thickness 0.5 μm; film deposition thicker than 0.5 μm was not possible due to peeling during the plating process).

Table 2 shows the evaluation results on Examples 1 through 6 and Comparative Examples 1 through 3. Evaluation items in Table 2 are adhesion layer, plating layer, plating film thickness, adhesive force, and surface roughness (Ra). The marks ◯ and X indicate sufficient adhesive force and insufficient adhesive force, respectively.

TABLE 2

| EXAMPLES | | | PLATING | | |
|---|---|---|---|---|---|
| AND | | | LAYER | | SURFACE |
| COMPARATIVE | ADHESION | | THICKNESS | ADHESIVE | ROUGHNESS |
| EXAMPLES | LAYER | PLATING LAYER | (μm) | FORCE | (μm) |
| Ex 1 | Ni chelate | NIMUDEN HDX | 3.0 | ◯ | 0.32 |
| Ex 2 | Ni chelate | MELPLATE | | | |
| | | NI-867 | 3.0 | ◯ | 0.33 |
| Ex 3 | Ni chelate | NIMUDEN LPY | 3.0 | ◯ | 0.30 |
| Ex 4 | Ni soap | NIMUDEN HDX | 3.0 | ◯ | 0.35 |
| Ex 5 | Ni soap | MELPLATE | 3.0 | ◯ | 0.36 |
| | | NI-867 | | | |
| Ex 6 | Ni soap | NIMUDEN LPY | 3.0 | ◯ | 0.34 |
| ComEx 1 | Sn/Pd | NIMUDEN HDX | 0.4 | X | 0.56 |
| ComEx 2 | Sn/Pd | MELPLATE | 0.7 | X | 0.57 |
| | | NI-867 | | | |
| ComEx 3 | Sn/Pd | NIMUDEN LPY | 0.5 | X | 0.61 |

Actual evaluation of adhesiveness of the Ni—P plating layer 4 was carried out according to the “Cross-cut Peeling Test” (Japanese Industrial Standards (JIS) K 5400 6.15) on the glass substrates 1 on which a Ni—P plating layer is plated by an electroless plating method. Mean surface roughness Ra was measured using an atomic force microscope (AFM) on the glass substrate 1 before and after plating. The mean surface roughness Ra before plating was 0.25 nm.

As shown in Table 2, the thickness of the Ni—P plating layer 4 formed on the glass substrate 1 by electroless plating attained 3.0 μm on the layers that were fabricated in Examples 1-6 by the treatment steps and conditions set forth in Table 1. Table 2 also confirms that the Ni—P plating layers 4 in the Examples exhibit sufficient adhesivity in the range from low phosphorus concentration to high phosphorus concentration. Surface roughness Ra was smaller than or equal to 0.5 nm and micro surface waviness Wa was smaller than or equal to 0.5 nm after the plating. It has been confirmed that the increase of surface roughness is insignificant and the surface roughness is sufficiently held within the range required by magnetic disks in Examples 1-6.

In contrast, the thickness of the Ni—P plating layer 4 formed on the glass substrate 1 by electroless plating fell in the range of 0.4 to 0.7 μm on the layers that were fabricated in Comparative Examples 1-3 according to the known technology. It has been shown that a thick film of 1.0 μm or greater was not possible, and the adhesiveness to a glass substrate 1 is significantly degraded.

As described so far, the method according to the present invention for forming a Ni—P plating layer comprises steps of degreasing and glass activation treatments on a glass substrate surface, application treatment of a nickel chelate agent or a nickel soap agent on the glass substrate surface, metallizing baking treatment of the nickel-containing agent, activation treatment of the nickel metallized film to form a nickel adhesion layer 2, treatment for forming a palladium catalyst layer 3 on the nickel adhesion layer 2, electroless Ni—P plating in the phosphorus concentration range of 1 to 13 wt % on the palladium catalyst layer 3 to form a Ni—P plating layer 4, and a heating treatment. Owing to these featured treatment processes, the Ni—P plating layer formed by electroless plating has a thickness of at least 1.0 μm and exhibits sufficient adhesivity, homogeneity, and smoothness. Therefore, a magnetic disk can be manufactured that is provided with a well-performing magnetic recording layer on a glass substrate.

A magnetic recording medium manufactured according to the present invention comprises a pretreatment layer including a nickel adhesion layer, a palladium catalyst layer, and a Ni—P plating layer sequentially laminated between the nonmagnetic substrate and the magnetic recording layer. The pretreatment layer achieves sufficient plating layer thickness, satisfactory adhesiveness with the substrate, and homogeneity. Therefore, a magnetic recording medium having a well-performing magnetic recording layer can be obtained.

Given the disclosure of the present invention, one versed in the art would appreciate that there may be other embodiments and modifications within the scope and spirit of the present invention. Accordingly, all modifications and equivalents attainable by one versed in the art from the present disclosure within the scope and spirit of the present invention are to be included as further embodiments of the present invention. The scope of the present invention accordingly is to be defined as set forth in the appended claims.

1. A method of pretreating a nonmagnetic substrate before forming a magnetic recording layer thereon, the method comprising steps of:
cleaning a surface of the nonmagnetic substrate;
forming a nickel layer on the surface of the nonmagnetic substrate after cleaning;
forming a palladium layer on the nickel layer; and
forming a Ni—P plating layer on the palladium layer.

2. The method according to claim 1, wherein:
the substrate is a glass substrate;
the step of cleaning the substrate surface includes a step of degreasing the substrate surface and a step of activating the substrate surface;
the step of forming the Ni layer includes a step of applying a nickel chelate agent or a nickel soap agent, a step of metallizing baking the nickel chelate agent or the nickel soap agent, and a step of activating the metallized nickel layer;
the step of forming the palladium layer includes a step of converting the palladium layer to a catalyst layer; and
the step of forming the Ni—P plating layer includes a step of electroless plating the Ni—P plating layer and a step of heating treating the Ni—P plating layer.

3. The method according to claim 1, wherein:
the step of forming the nickel layer includes a step of baking a nickel chelate agent or a nickel soap agent to form a nickel metallic film;
the step of forming the palladium layer includes a step of bonding palladium with a surface of the nickel metallic film; and
the step of forming the Ni—P plating layer is carried out by electroless plating after the step of bonding, and includes a subsequent step of heating treating the Ni—P plating layer.

4. The method according to claim 1, wherein surface roughness of the substrate surface after the pretreatment is at most 0.5 nm and micro surface waviness is at most 0.5 nm.

5. The method according to claim 2, wherein the nickel chelate agent has a structure represented by Ni(CᵢH₂ᵢ₊₁COCⱼH₂ⱼCOCₖH₂ₖ₊₁), where i, j, and k are positive integers.

6. The method according to claim 2, wherein the nickel soap agent has a structure represented by one of Ni(—OOCCH(CₙH₂ₙ₊₁)CₚH₂ₚ₊₁)₂ and Ni(—OOCCₘH₂ₘ₊₁)₂ where m, n, and o each are a positive integer of one or greater.

7. The method according to claim 2, wherein the step of metallizing baking is carried out in an inert gas atmosphere and at a temperature in a range of 250° C. to 400° C.

8. The method according to claim 2, wherein the step of converting the palladium layer to a catalyst layer is a treatment of palladium chloride.

9. The method according to claim 1, wherein the Ni—P plating layer contains phosphorus in a range of 1.0 wt % to 13.0 wt % and has a thickness of at least 1.0 μm.

10. The method according to claim 2, wherein the heating treatment is carried out at a temperature in a range of 250° C. to 300° C. for at least 1 hr.

11. A magnetic recording medium comprising:
a nonmagnetic substrate;
a magnetic recording layer formed above the substrate; and
a pretreatment layer formed between the substrate and the magnetic recording,
wherein the pretreatment layer comprises a nickel adhesion layer formed on the substrate, a palladium catalyst layer formed on the adhesion layer, and a Ni—P plating layer formed on the catalyst layer, and
wherein the nonmagnetic substrate is pretreated before forming a magnetic recording layer thereon by the method of pretreating the substrate defined by the steps of:
cleaning a surface of the nonmagnetic substrate;
forming a nickel layer on the surface of the nonmagnetic substrate after cleaning;
forming a palladium layer on the nickel layer; and
forming a Ni—P plating layer on the palladium layer.

12. The magnetic recording medium according to claim 11, wherein:
the substrate is a glass substrate;
the step of cleaning the substrate surface includes a step of degreasing the substrate surface and a step of activating the substrate surface;
the step of forming the Ni layer includes a step of applying a nickel chelate agent or a nickel soap agent, a step of metallizing baking the nickel chelate agent or the nickel soap agent, and a step of activating the metallized nickel layer;
the step of forming the palladium layer includes a step of converting the palladium layer to a catalyst layer; and
the step of forming the Ni—P plating layer includes a step of electroless plating the Ni—P plating layer and a step of heating treating the Ni—P plating layer.

13. The magnetic recording medium according to claim 11, wherein:
the step of forming the nickel layer includes a step of baking a nickel chelate agent or a nickel soap agent to form a nickel metallic film;
the step of forming the palladium layer includes a step of bonding palladium with a surface of the nickel metallic film; and
the step of forming the Ni—P plating layer is carried out by electroless plating after the step of bonding, and includes a subsequent step of heating treating the Ni—P plating layer.

14. The magnetic recording medium according to claim 11, wherein surface roughness of the substrate surface after the pretreatment is at most 0.5 nm and micro surface waviness is at most 0.5 nm.

15. The magnetic recording medium according to claim 12, wherein the nickel chelate agent has a structure represented by Ni(CᵢH₂ᵢ₊₁COCⱼH₂ⱼCOCₖH₂ₖ₊₁), where i, j, and k are positive integers.

16. The magnetic recording medium according to claim 12, wherein the nickel soap agent has a structure represented by one of Ni(—OOCCH(CₙH₂ₙ₊₁)CₚH₂ₚ₊₁)₂ and Ni(—OOCCₘH₂ₘ₊₁)₂ where m, n, and o each are a positive integer of one or greater.

17. The magnetic recording medium according to claim 12, wherein the step of metallizing baking is carried out in an inert gas atmosphere and at a temperature in a range of 250° C. to 400° C.

18. The magnetic recording medium according to claim 12, wherein the step of converting the palladium layer to a catalyst layer is a treatment of palladium chloride.

19. The magnetic recording medium according to claim 11, wherein the Ni—P plating layer contains phosphorus in a range of 1.0 wt % to 13.0 wt % and has a thickness of at least 1.0 μm.

20. The magnetic recording medium according to claim 12, wherein the heating treatment is carried out at a temperature in a range of 250° C. to 300° C. for at least 1 hr.
